(19) United States
(12) Patent Application Publication
(10) Pub. No.: US 2008/0224183 A1
(43) Pub. Date: Sep. 18, 2008

(54) Method for Manufacturing a Compound Semiconductor Field Effect Transistor Having a Fin Structure, and Compound Semiconductor Field Effect Transistor Having a Fin Structure

(76) Inventor: Muhammad Nawaz, Norsborg (SE)

Correspondence Address: SLATER & MATSIL LLP, 17950 PRESTON ROAD, SUITE 1000, DALLAS, TX, 75252, US

(21) Appl. No.: 12/128,239

(22) Filed: May 28, 2008

Related U.S. Application Data
(63) Continuation of application No. PCT/DE2006/002221, filed on Dec. 12, 2006.

(30) Foreign Application Priority Data
Dec. 12, 2005 (DE) 10 2005 059 231.7

(51) Int. Cl. H01L 21/285; H01L 21/336

(52) U.S. Cl. 257/279; 438/285; 257/E29.089; 257/E21.172

(57) ABSTRACT

In another embodiment, the invention provides a compound semiconductor field effect transistor having a fin structure. A first layer is formed on or above a substrate, wherein the first layer contains a first compound semiconductor material. A second layer is formed on the first layer, wherein the second layer comprises a second compound semiconductor material. A third layer is formed on the second layer, wherein the third layer comprises a third compound semiconductor material. A cap layer is formed on at least one partial region of the third layer, wherein the cap layer comprises a fourth compound semiconductor material. The second layer, the third layer and the cap layer are patterned in such a way that a fin structure is formed. A first source/drain region is formed from a first partial region of the cap layer, and a second source/drain region is formed from a second partial region of the cap layer. A gate region is formed on at least one partial region of at least one sidewall of the fin structure and/or on a partial region of an upper surface of the third layer.

This application is a continuation of co-pending International Application No. PCT/DE2006/002221, filed Dec. 12, 2006, which designated the United States and was not published in English, and which is based on German Application No. 10 2005 059 231.7 filed Dec. 12, 2005, both of which applications are incorporated herein by reference.

### TECHNICAL FIELD

The invention relates to a method for the manufacturing of a compound semiconductor field effect transistor having a fin structure, and to a compound semiconductor field effect transistor having a fin structure.

### BACKGROUND

Metal semiconductor field effect transistor (MESFET) devices based on gallium arsenide (GaAs), that is to say a compound semiconductor including the chemical element gallium (Ga) from the third main group of the periodic system and the chemical element arsenic (As) from the fifth main group of the periodic system, are well-known devices having three electrical terminals (three-terminal devices), which devices are used in diverse analog applications and digital applications at microwave frequencies. Compared with conventional silicon technology (Si technology), GaAs material systems have better transport properties (e.g., five times higher electron mobility and higher low field electron velocity) and therefore have a better noise performance at microwave frequencies and millimeter wave frequencies.

In contrast to an Si substrate, a GaAs substrate is semi-insulating and consequently enables a greater device functionality through epitaxial growth of different layers on the same substrate. A GaAs substrate is therefore well suited to integration in optoelectronic devices.

Since GaAs has a larger band gap than silicon, GaAs-based integrated circuits (ICs) can be used at higher temperatures and thus at higher power levels.

In many digital IC designs a principal aim hitherto has been to reduce the power consumption without simultaneously sacrificing the speed performance. Similarly to silicon-based devices, GaAs-based devices, too, have also been aggressively miniaturized or scaled down to the sub-micron range (e.g. 2 μm to 0.1 μm). In the sub-100-nm range, the device performance, to put it another way the performance of a device, is often limited by the so-called short-channel effects, whereby further scaling becomes difficult, if not even impossible. These effects are usually manifested in the form of a reduction in the transconductance, an increase in the output conductance and a shift in the threshold voltage if the gate length is reduced.

Another manifestation of the short-channel effects consists in an increase in the sub-threshold current. Particularly for low-power applications, or for high-speed applications, in which the devices operate near the pinch-off region, precise control of the sub-threshold drain current and of the threshold voltage is necessary.

In order to overcome future technological challenges, therefore, there is a need for new device architectures and/or new material combinations which have a better low-power performance and a better high-speed performance.

Field effect transistor devices having a fin structure (fin field effect transistor, FinFET) have been proposed in this connection.

A FinFET is a structure having two gates (so-called double-gated structure) which contains a channel region or channel formed in a vertical fin. The use of two lateral gates or side gates in FinFETs is advantageous in order to suppress the short-channel effects. A FinFET, with regard to its layout and its production, is comparable with existing planar MOSFETs (metal oxide semiconductor field effect transistor). It likewise enables a selection or bandwidth of channel lengths, CMOS (complementary metal oxide semiconductor) compatibility and a high packing density.

Various FinFET architectures, which are based on silicon (Si) material systems and on silicon-silicon/germanium (Si/SiGe) material systems, and improve the performance of the devices as far as the control of the short-channel effects and the current driver capability are concerned, have been reported to date (see, e.g., US 2005/073005 A1; WO 2005/010944 A2; WO 2004/049406 A1; WO 2004/068585 A1).

Only planar (that is to say that all three device electrodes are situated on one and the same GaAs surface) or quasi-planar (i.e., recess-gate structures) GaAs-based MESFETs have been disclosed hitherto, see, e.g., U.S. Pat. No. 5,536,666; U.S. Pat. No. 5,514,606; EP 0 517 443 A2; U.S. Pat. No. 5,350,702. The previous documents concentrated principally on improving burn-out and/or the breakdown voltage characteristic (U.S. Pat. No. 5,536,666; U.S. Pat. No. 5,514,606), an increased Schottky barrier height (EP 0 517 443 A2) and an improved gain performance through the use of a dual-gate structure, that is to say two gate electrodes situated close together and between the source-drain contacts (U.S. Pat. No. 5,350,702). However, no FinFET structures or MuGFET structures are known in the art for GaAs material systems, or more generally for compound semiconductor material systems.

Other references, such as U.S. Pat. No. 5,432,356; US 2005/0205859 A1; US 2002/0139994 A1 disclose field effect transistor devices having a plurality of layers formed one above another, which layers each contain a III-V semiconductor material.

### SUMMARY OF THE INVENTION

Aspects of the invention provide a design for a double-gate or multi-gate compound semiconductor field effect transistor having a fin structure.

As an example, a method is disclosed to manufacture a compound semiconductor field effect transistor having a fin structure. A compound semiconductor field effect transistor having a fin structure is also disclosed.

A number of exemplary configurations of the invention are disclosed. The further configurations of the invention that are described in connection with the method for the manufacturing of a compound semiconductor field effect transistor having a fin structure also apply analogously to the compound semiconductor field effect transistor having a fin structure.

A first embodiment of the invention provides a method for the manufacturing of a compound semiconductor field effect transistor having a fin structure. A first layer is formed on or above a substrate. The first layer contains a first compound semiconductor material. A second layer is formed on the first layer. The second layer contains a second compound semiconductor material. A third layer is formed on the second layer. The third layer contains a third compound semiconductor material. A cap layer is formed on at least one partial region of the third layer. The cap layer contains a fourth compound semiconductor material. A fin structure is formed by patterning the second layer, the third layer and the cap layer. A first source/drain region is formed from a first partial region of the cap layer and a second source/drain region is formed from a second partial region of the cap layer. A gate region is formed on at least one partial region of at least one sidewall of the fin structure and/or on a partial region of an upper surface of the third layer.

In another embodiment, the invention provides a compound semiconductor field effect transistor having a fin structure. A first layer is formed on or above a substrate, wherein the first layer contains a first compound semiconductor material. A second layer is formed on the first layer, wherein the second layer comprises a second compound semiconductor material. A third layer is formed on the second layer, wherein the third layer comprises a third compound semiconductor material. A cap layer is formed on at least one partial region of the third layer, wherein the cap layer comprises a fourth compound semiconductor material. The second layer, the third layer and the cap layer are patterned in such a way that a fin structure is formed. A first source/drain region is formed from a first partial region of the cap layer, and a second source/drain region is formed from a second partial region of the cap layer. A gate region is formed on at least one partial region of at least one sidewall of the fin structure and/or on a partial region of an upper surface of the third layer.

One aspect of the invention can be seen in the fact that a field effect transistor having a fin structure, for example, a fin field effect transistor (FinFET) or a multi-gate field effect transistor (MuGFET), based on compound semiconductor materials such as III-V compound semiconductor materials, for example, is realized.

The expressions “fin structure” and “fin” are used alternately and synonymously hereinafter. A fin field effect transistor (FinFET) is understood to mean a field effect transistor having a fin structure or a fin. A multi-gate field effect transistor (MuGFET) is understood to mean a fin field effect transistor (FinFET) in which the channel is driven by a gate structure from more than two sides. A MuGFET in which the channel is driven from three sides is also referred to as a triple-gate field effect transistor or as a tri-gate field effect transistor.

Another aspect of the invention can be seen in the fact that a design for a FinFET having two gates (double-gated FinFET) and a tri-gate FET or a multi-gate FET based on compound semiconductor materials is provided. The invention provides, in particular, a method for the manufacturing of a FinFET or of a multi-gate FET based on high-mobility material systems which have very good (charge carrier) transport properties and can therefore be advantageously used for applications in the microwave frequency range and in the millimeter wave frequency range.

By way of example, a FinFET or MuGFET based on GaAs material is provided. Similarly to a planar MESFET, a GaAs-MuGFET can be regarded as a device having three (electrical) terminals (three-terminal device), which device has a first terminal, the source terminal or source, a second terminal, the drain terminal or drain, and a third terminal, the gate terminal or gate. The majority charge carriers (electrons in this case) can flow from the source region to the drain region and in the process can pass the gated region along a channel. The current through the channel can be controlled by the third terminal, that is to say the gate terminal.

The length of the gate can usually be used to influence or define the speed performance of the device (that is to say of the transistor), and hence how fast, e.g., a circuit can operate.

Another aspect of the invention can be seen in the fact that in the compound semiconductor field effect transistor having a fin structure, more than one gate can be used for more effectively controlling the channel electrons and, consequently, for suppressing the short-channel effects discussed above. The channel for a GaAs-based FinFET or MuGFET can be formed as a thin rectangular island (bridge) composed of GaAs material having a predetermined height, which island or bridge is usually referred to as a “fin”. The gate can envelope the fin in such a way that the channel is controlled from both sides of the vertical partial region of the fin structure, whereby a gate control is provided which is better than in the case of planar MESFETs having only a single gate (single-gate MESFET).

One aspect of the invention can be seen in the fact that the invention provides a layout and a method for the manufacturing of compound-semiconductor-material-based fin field effect transistors (FinFETs) having two lateral gates, and multi-gate field effect transistors (MuGFETs) or tri-gate field effect transistors having three gates (two lateral gates and a third gate on the upper surface of the fin).

Both types of devices, i.e., FinFETs and MuGFETs, can be manufactured in the same process sequence, e.g., using the same mask and without additional process steps. The total effective width of the device is twice the fin height (2×H_{fin}).

One advantage of the invention can be seen in the fact that the layout and the manufacturing method are similar to those of already existing planar GaAs-MESFETs. By way of example, the devices can be processed with the aid of a combination of conventional optical lithography and electron lithography techniques.

In accordance with one configuration of the invention, the substrate used for the compound semiconductor field effect transistor having a fin structure contains a semi-insulating material.

In accordance with another configuration of the invention, the substrate contains a III-V compound material.

In the case of a substrate containing a III-V compound material, the substrate can contain a gallium arsenide material (GaAs material), e.g., a layer composed of a semi-insulating GaAs material.

In accordance with another configuration of the invention, the substrate contains an indium phosphide material (InP material).

In another configuration of the invention, prior to forming the first layer, a buffer layer is formed on the substrate, and the first layer is formed on the buffer layer.

The buffer layer can be formed using a growth method such as, for example, a molecular beam epitaxy (MBE) growth method or a metal organic chemical vapor deposition (MOCVD) method.

The buffer layer can contain a fifth compound semiconductor material.

The buffer layer can improve the quality of a subsequently formed material layer, e.g., the quality of the first layer, compared with forming the material layer (e.g., the first layer) directly on the substrate.

In accordance with another configuration of the invention, at least one of the following layers contains a III-V compound semiconductor material: the first layer; the second layer; the third layer; the cap layer; the buffer layer.

In accordance with another configuration of the invention, at least one of the following layers contains a GaAs material: the second layer, the third layer, the cap layer, the buffer layer.

By way of example, the buffer layer can contain a non-doped or undoped GaAs material, e.g., in the case of a GaAs substrate. As an alternative, the buffer layer can contain a non-doped (undoped) InP material, e.g., in the case of an InP substrate.

In another configuration of the invention, the buffer layer has a thickness of approximately 500 nm±100 nm.

In accordance with another configuration of the invention, at least one of the following layers is formed using a growth method such as, for example, a molecular beam epitaxy (MBE) growth method or a metal organic chemical vapor deposition (MOCVD) method: the first layer, the second layer, the third layer, the cap layer, the buffer layer.

In accordance with another configuration of the invention, the first layer contains a semiconductor material having a large band gap (wide-band-gap semiconductor material), in other words a semiconductor material having a high energy band gap, e.g., having an energy band gap of between approximately 1.5 eV and 2.2 eV.

Clearly, the first layer, which contains a wide-band-gap material, that is to say a material having a high energy band gap, effectively suppresses the charge carrier transport, in other words the movement of the charge carriers, into the substrate by creating a potential barrier. The first layer is therefore also referred to as a barrier layer or as a separating layer.

The thickness of the first layer (or barrier layer) can be chosen such that the time required for forming the barrier layer (e.g., by means of a growth method) is minimized, while at the same time an effective barrier for charge carrier transport is nevertheless ensured.

In accordance with one configuration of the invention, the first layer contains an AlAs material, e.g., a non-doped (undoped) AlAs material. In this case, the thickness of the first layer can be approximately 20 nm to 60 nm. However, the first layer can also have other dimensions. An undoped AlAs material can have an energy band gap of approximately 2.16 eV.

In another configuration of the invention, the first layer contains an Al_{0.3}Ga_{0.7}As material, e.g. a non-doped (undoped) Al_{0.3}Ga_{0.7}As material, and the thickness of the first layer can be approximately 10 nm to 20 nm in this case. However, the first layer can also have other dimensions. An undoped Al_{0.3}Ga_{0.7}As material can have an energy band gap of approximately 1.785 eV.

In accordance with another configuration of the invention, the first layer contains an Al_{0.48}In_{0.52}As material, e.g., a non-doped (undoped) Al_{0.48}In_{0.52}As material, and the thickness of the first layer can be approximately 100 nm to 500 nm in this case. However, the first layer can also have other dimensions. An undoped Al_{0.48}In_{0.52}As material can have an energy band gap of approximately 1.5 eV.

In accordance with another configuration of the invention, the second layer is formed as a spacer layer, and the third layer formed on the second layer, i.e., the spacer layer, is formed as a channel layer or as a channel of the field effect transistor.

The spacer layer can contain a non-doped (undoped) GaAs material or an undoped InP material, and the spacer layer can have a thickness of approximately 50 nm to 100 nm. However, the spacer layer can also have other dimensions.

In accordance with another configuration of the invention, the second layer is formed as a channel layer or as a channel of the field effect transistor, and the third layer formed on the second layer, i.e., on the channel layer, contains a wide-band-gap material, that is to say a material having a high energy band gap.

In the case where the third layer contains a wide-band-gap material, that is to say a material having a large energy band gap, the third layer can contain, for example, an Al_{0.3}Ga_{0.7}As material having a thickness of approximately 10 nm to 20 nm, or an Al_{0.48}In_{0.52}As material having a thickness of approximately 10 nm to 30 nm.

In accordance with another configuration of the invention, the channel layer contains a GaAs material, and the GaAs material of the channel layer is doped with an n-type dopant such as, e.g., silicon (Si).

In accordance with another configuration of the invention, the channel layer contains an In_{0.53}Ga_{0.47}As material, and the In_{0.53}Ga_{0.47}As material of the channel layer is doped with an n-type dopant such as, e.g., silicon (Si).

In accordance with another configuration of the invention, the n-doped channel layer, e.g. the n-doped GaAs channel layer or the n-doped In_{0.53}Ga_{0.47}As channel layer, has a high dopant concentration (n⁺-type doping).

By way of example, the n-doped (or n⁺-doped) channel layer can have a dopant concentration of approximately 0.5×10¹⁸ cm⁻³ to 5.0×10¹⁸ cm⁻³.

A GaAs channel layer formed on a GaAs spacer layer can have a thickness of approximately 20 nm to 50 nm, and an In_{0.53}Ga_{0.47}As channel layer formed on an InP spacer layer can have a thickness of approximately 10 nm to 30 nm. In alternative configurations, however, the channel layer can have other dimensions.

In accordance with another configuration of the invention, the cap layer contains a GaAs material, and the GaAs material of the cap layer is doped with an n-type dopant such as, e.g., silicon (Si).

In another configuration of the invention, the GaAs cap layer has a thickness of approximately 20 nm to 50 nm. However, the GaAs cap layer can also have other dimensions.

In accordance with another configuration of the invention, the cap layer has an In_{0.53}Ga_{0.47}As material, and the In_{0.53}Ga_{0.47}As material of the cap layer is doped with an n-type dopant such as, e.g., silicon (Si).

In another configuration of the invention, the In_{0.53}Ga_{0.47}As cap layer has a thickness of approximately 10 nm to 20 nm. However, the In_{0.53}Ga_{0.47}As cap layer can also have other dimensions.

In accordance with another configuration of the invention, the n-doped cap layer has a dopant concentration of approximately 1×10¹⁸ cm⁻³ to 5×10¹⁸ cm⁻³.

In accordance with another configuration of the invention, the fin structure (fin) has a width of approximately 25 nm to 50 nm. However, the width of the fin structure can also have other dimensions.

In accordance with another configuration of the invention, the gate region is formed using an electron beam lithography (EBL) method.

In another configuration of the invention, forming the gate region includes forming a gate recess.

The gate recess can be formed using a wet etching method or a dry etching method.

In accordance with another configuration of the invention, forming the gate region furthermore includes forming an insulating layer on the at least one partial region of the at least one sidewall of the fin structure and/or on the partial region of the upper surface of the third layer (e.g., the channel layer), and forming an electrically conductive layer on the insulating layer.

The electrically conductive layer can be formed using an electron beam evaporation method.

In alternative configurations of the invention, the channel layer can contain an InGaAs material or an InP material.

In accordance with one alternative configuration of the invention, the distance between the first source/drain region and the second source/drain region along the fin structure is approximately 2 μm to 3 μm. However, the distance can also have other dimensions.

In another configuration of the invention, the length of the gate region is approximately 30 nm to 100 nm. However, the length of the gate region can also have other dimensions.

In accordance with another configuration of the invention, the distance between the gate region and the first source/drain region is approximately 0.5 μm to 0.8 μm, and the distance between the gate region and the second source/drain region can likewise be approximately 0.5 μm to 0.8 μm. However, the distances mentioned above can also have other dimensions.

The electrically conductive layer of the gate region can comprise titanium (Ti) and/or platinum (Pt) and/or gold (Au). However, the electrically conductive layer can also contain other suitable, electrically conductive materials.

In accordance with another configuration of the invention, the first source/drain region and/or the second source/drain region are formed using a lithography method such as an optical lithography method, for example.

In accordance with another configuration of the invention, a first source/drain contact is formed on the first partial region of the cap layer for the purpose of making electrical contact with the first source/drain region, and a second source/drain contact is formed on the second partial region of the cap layer for the purpose of making electrical contact with the second source/drain region.

In another configuration of the invention, the first source/drain contact, which makes electrical contact with the first source/drain region, and the second source/drain contact, which makes electrical contact with the second source/drain region, comprise nickel (Ni) and/or germanium (Ge) and/or gold (Au).

To put it another way, nickel (Ni), germanium (Ge) or gold (Au) can be used for a source/drain metallization step during the formation of the first source/drain contact on the cap layer, more precisely on the first partial region of the cap layer, which forms the first source/drain region, and/or during the formation of the second source/drain contact on the cap layer, more precisely on the second partial region of the cap layer, which forms the second source/drain region. However, the first source/drain contact and/or the second source/drain contact can also contain other suitable, electrically conductive materials.

The first source/drain contact and/or the second source/drain contact can be formed on an upper surface of the cap layer, more precisely on an upper surface of the first source/drain region, which is formed from the first partial region of the cap layer, and on an upper surface of the second source/drain region, which is formed from the second partial region of the cap layer.

In accordance with another configuration of the invention, an anneal step or a thermal annealing step (e.g., a rapid thermal anneal (RTA)) is carried out after forming the first source/drain contact and/or after forming the second source/drain contact. By way of example, for GaAs-based FinFET/MuGFET devices, an anneal step can be carried out at a temperature of approximately 400° C. to 450° C., and for InGaAs/InP-based FinFETs/MuGFETs, an anneal step can be carried out at a temperature of approximately 300° C. to 350° C.

In another configuration of the invention, the fin structure is formed using an electron beam lithography (EBL) method and/or a dry etching method. In other words, the patterning of the second layer, of the third layer and of the cap layer for forming the fin structure can be realized using an EBL method and/or a dry etching method, which methods ensure, e.g., a sufficient accuracy for obtaining the desired fin structure dimensions.

In accordance with another configuration of the invention, a passivation layer is formed on at least one partial region of the cap layer and/or on at least one partial region of the third layer between the gate region and the first source/drain region and/or between the gate region and the second source/drain region.

The passivation layer can be formed using a growth method such as, for example, a plasma enhanced chemical vapor deposition (PECVD) method or a cathode sputtering method (sputter method) such as, for example, a DC sputter method or an RF sputter method, as is well known in the art.

The passivation layer can comprise a silicon nitride material (Si₃N₄ material). However, the passivation layer can also contain other suitable materials.

In accordance with another configuration of the invention, the passivation layer can have a thickness of approximately 50 nm to 150 nm. However, the thickness of the passivation layer can also have other dimensions.

Clearly, the passivation layer covers the gate-source interspace region and the gate-drain interspace region and insulates the devices.

### BRIEF DESCRIPTION OF THE DRAWINGS

Exemplary configurations of the invention are shown in the figures and are described thoroughly below. In the figures, similar or identical elements, in so far as is practical, are provided with similar or identical reference symbols. The illustrations shown in the figures are schematic and therefore not shown as true to scale.

In the figures:

FIG. 1A to FIG. 1I and FIG. 2A to FIG. 2D show different process steps of a method for the production of a compound semiconductor field effect transistor comprising a fin structure in accordance with an exemplary embodiment of the present invention; and

FIG. 3 to FIG. 5 show compound semiconductor field effect transistors comprising a fin structure in accordance with alternative exemplary embodiments of the present invention.

### DETAILED DESCRIPTION OF ILLUSTRATIVE EMBODIMENTS

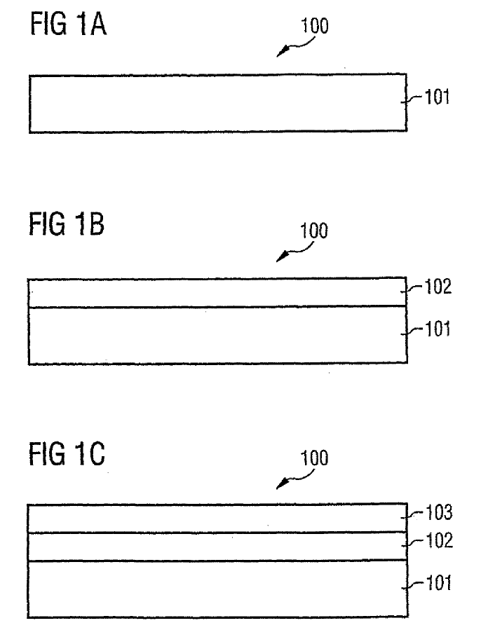

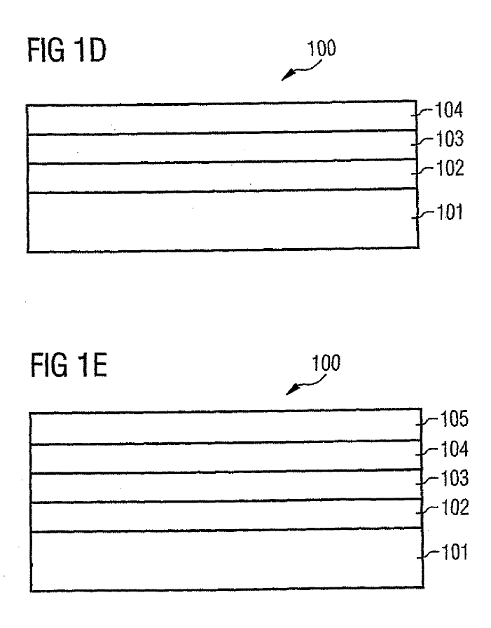

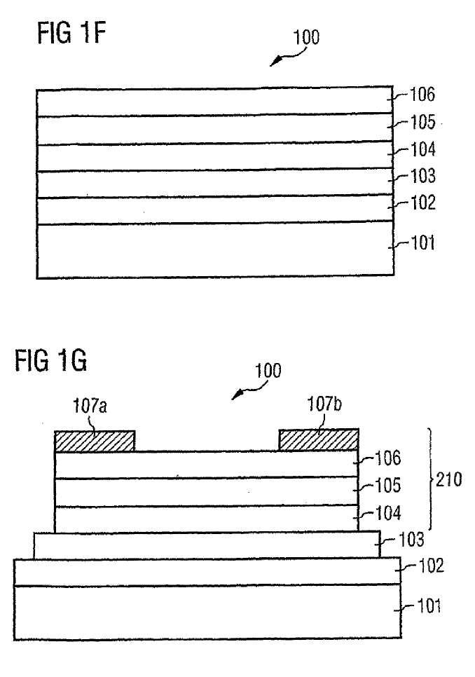

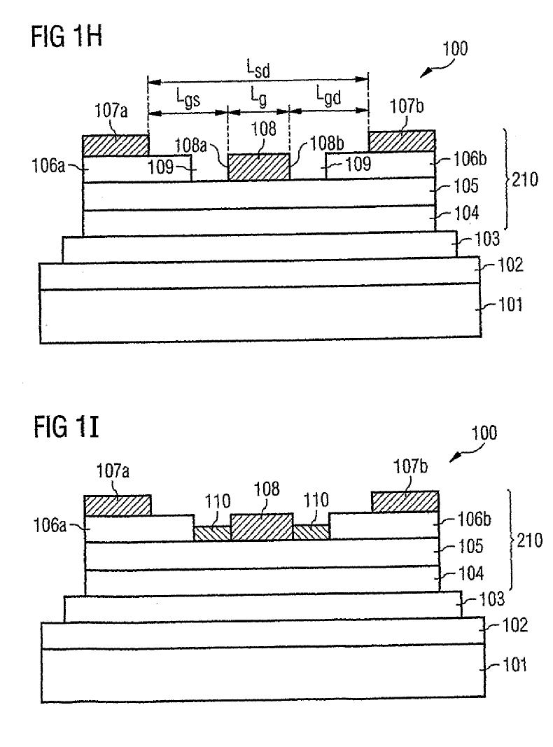

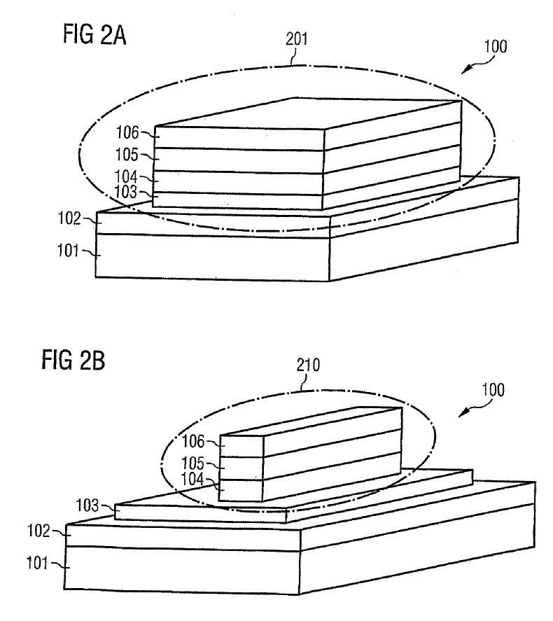

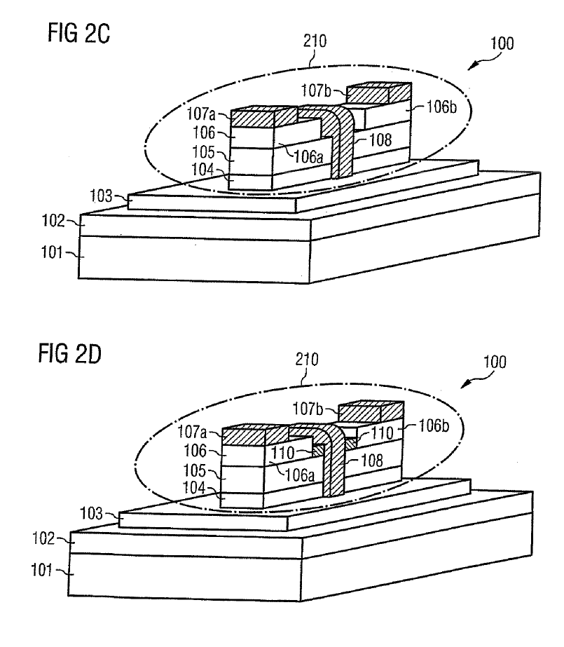

FIG. 1A to FIG. 1I show, as cross-sectional views, different process steps of a method for the manufacturing of a compound semiconductor field effect transistor (FET) having a fin structure (also referred to hereinafter as “compound semiconductor field effect transistor” or as “field effect transistor”, for the sake of simplicity) for example, of a FinFET or of a MuGFET in accordance with an exemplary embodiment of the present invention. FIG. 2A to FIG. 2D show process steps of the method as three-dimensional perspective views.

The manufacturing of a compound semiconductor field effect transistor based on GaAs technology is described in accordance with the exemplary embodiment illustrated. The material combinations used are therefore specific to a GaAs material system. In alternative configurations of the invention, however, a compound semiconductor field effect transistor based on other compound semiconductor material systems, e.g., other III-V material systems, can be obtained by using other suitable material combinations.

FIG. 1A shows a cross-sectional view of a layer arrangement 100 in a first process step of the method. The layer arrangement 100 has a semi-insulating GaAs substrate 101 or GaAs wafer 101.

FIG. 1B shows the layer arrangement 100 in another process step, in which a buffer layer 102 is formed on the substrate 101. The buffer layer 102 contains an undoped GaAs material and can have a thickness of approximately 500 nm±100 nm. The buffer layer 102 can be formed on the substrate 101 using a growth method such as, for example, a molecular beam epitaxy (MBE) growth method or a metal organic chemical vapor deposition (MOCVD) method. The buffer layer can improve the quality of the material formed after the buffer layer 102 (e.g., the first layer 103, see FIG. 1C), compared with direct growth of the material on the substrate.

The buffer layer 102 can be omitted in alternative configurations of the invention.

FIG. 1C shows the layer arrangement 100 in another process step, in which a first layer 103 is formed on the buffer layer 102, for example, by means of a growth method such as, for example, a molecular beam epitaxy (MBE) growth method or a metal organic chemical vapor deposition (MOCVD) method. The first layer 103 has a thin layer composed of an undoped wide-band-gap AlAs material (that is to say an AlAs material having a large energy band gap), in order to effectively suppress the charge carrier transport into the substrate 101 by creating a potential barrier. The first layer 103 is therefore also referred to as a barrier layer or as a separating layer. The first layer 103 (barrier layer 103) can have a thickness of approximately 20 nm to 60 nm, which suffices to minimize the growth time and nevertheless to ensure an effective barrier.

FIG. 1D shows the layer arrangement 100 in another process step, in which a second layer 104 is formed on the first layer 103, for example, with the aid of a growth method such as, for example, a molecular beam epitaxy (MBE) growth method or a metal organic chemical vapor deposition (MOCVD) method. The second layer 104, which serves as a spacer layer, contains an undoped GaAs material, and the second layer 104 (spacer layer) can have a thickness of approximately 50 nm to 100 nm.

FIG. 1E shows the layer arrangement 100 in another process step, in which a third layer 105, which contains a GaAs material, is formed on the second layer 104, for example, with the aid of a growth method such as, for example, a molecular beam epitaxy (MBE) growth method or a metal organic chemical vapor deposition (MOCVD) method. The GaAs material of the third layer 105 is heavily n-doped (n⁺-doped) with a dopant concentration of, e.g., approximately 0.5×10¹⁸ cm⁻³ to 5.0×10¹⁸ cm⁻³. Silicon (Si), for example, can be used as dopant. The third layer 105 can have a thickness of approximately 20 nm to 50 nm.

Clearly, in a finished field effect transistor device of the present invention, the third layer 105 serves as a channel layer 105, in other words as an electrically conductive channel 105, of the field effect transistor.

FIG. 1F shows the layer arrangement 100 in another process step, in which a cap layer 106 containing a GaAs material is formed on the third layer 105, for example, with the aid of a growth method such as, for example, a molecular beam epitaxy (MBE) growth method or a metal organic chemical vapor deposition (MOCVD) method. The GaAs material of the cap layer 106 is n-doped with a dopant concentration of, for example, approximately 1×10¹⁸ cm⁻³ to 5×10¹⁸ cm⁻³. Silicon (Si), for example, can be used as dopant. The cap layer 106 can have a thickness of approximately 20 nm to 50 nm.

Clearly, the cap layer 106, or at least parts of the cap layer 106, serves for forming the source/drain regions 106a, 106b of the field effect transistor, see FIG. 1H and FIG. 2C.

In another process step of the method, using a standard photoresist mask such as, e.g., a standard positive resist mask, a lithography step (e.g., optical contact lithography) and a wet etching step, a mesa insulation is created, wherein a mesa structure 201 is formed by patterning the layer arrangement 100 with the aid of wet etching of the layer arrangement 100 down to the buffer layer 102, i.e., down to the upper surface of the buffer layer 102, as is illustrated in FIG. 2A, which shows a perspective view of the layer arrangement 100 after the mesa insulation.

In alternative configurations of the invention, the wet etching of the layer arrangement 100 can be stopped at the upper surface of the first layer 103 (i.e., of the barrier layer 103) or at the upper surface of the substrate 101.

The wet etching step can be carried out using a wet etching solution of H₂SO₄:H₂O₂:H₂O (4:1:35), and by etching for a time duration of approximately 30 s to 40 s.

In another configuration of the invention, such as, for example, in the case of indium phosphide/indium gallium arsenide (InP/InGaAs) based FinFETs or MuGFETs, other wet etching solutions can be used such as, for example, H₃PO₄:H₂O₂:H₂O (1:1:25) for wet etching with a time duration of approximately 30 s to 40 s for the mesa insulation.

In another process step of the method, a fin structure 210 having a rectangular cross section is formed by patterning the second layer 104 (spacer layer 104), the third layer 105 (channel layer 105) and the cap layer 106, as is illustrated in FIG. 2B, which shows a perspective view of the layer arrangement 100 after the formation of the fin structure 210.

The fin 210 can be formed using an electron beam lithography (EBL) method and a dry etching method. In the context of this process step, firstly a thin silicon nitride layer (Si₃N₄ layer) can be formed as a mask on the cap layer 106 (e.g., by deposition), for example, with a thickness of approximately 50 nm, and afterward an electron-sensitive resist material (electron beam resist) can be applied to the mask (e.g., by spin-coating). The wafer can subsequently be exposed by means of an electron beam and then developed.

The silicon nitride material can be etched away, such that only the fin surface remains as mask. The rectangular fin 210 can be obtained by dry etching. The width of the fin 210 obtained can vary from approximately 25 nm to 50 nm.

FIG. 1G shows a cross-sectional view of the layer arrangement 100 in another process step, wherein the definition of the ohmic source/drain contacts of the field effect transistor is illustrated.

A first source/drain contact 107a is formed on a first partial region of the cap layer 106, and a second source/drain contact 107b is formed on a second partial region of the cap layer 106.

The definition of the source/drain contacts can be achieved by optical lithography and a lift-off method.

The distance L_{sd} between the first source/drain contact 107a and the second source/drain contact 107b can be approximately 1 μm to 3 μm, see FIG. 1H.

The first source/drain contact 107a and the second source/drain contact 107b can each have a layer arrangement comprising a nickel layer (Ni layer) having a thickness of approximately 18 nm, a germanium layer (Ge layer) arranged on the Ni layer and having a thickness of approximately 50 nm, and a gold layer (Au layer) arranged on the Ge layer and having a thickness of approximately 150 nm.

The materials (i.e., the metals) used for the source/drain contacts 107a, 107b are, for example, well suited to GaAs-based or InGaAs/InP-based FinFET devices or MuGFET devices. The metals can be deposited, for example, with the aid of an electron beam evaporation method, as is well known in the art.

In addition to the source/drain metallization, a rapid thermal anneal can be effected, e.g., at 400° C. to 450° C. for GaAs-based FinFET/MuGFET devices or at 300° C. to 350° C. for InGaAs/InP-based FinFETs/MuGFETs.

Referring to FIG. 1H and FIG. 2C, another process step of the method will now be described, in which a gate region (or gate) 108 is formed by a combination of a gate lithography method, a wet etching method and/or a dry etching method and a gate metallization.

Firstly, a gate lithography step can be performed, e.g., by depositing a layer composed of an electron-sensitive resist material on the cap layer 106 and by subsequent exposure by means of an electron beam. After development of the electron-sensitive resist and prior to a gate metallization evaporation step, the cap layer 106 can be subjected to wet etching, such that the gate 108 is formed directly on the third layer 105 (i.e., the GaAs channel layer 105).

To put it another way, a gate recess is formed, e.g., by using an electron beam lithography (EBL) process step and a wet etching process step and/or a dry etching process step for uncovering the upper surface of the underlying channel layer 105, or, more precisely, the upper surface of that partial region of the channel layer 105 which lies below the removed partial region of the cap layer 106.

After the gate recess has been formed, the cap layer 106 has been removed in the region of the field effect transistor, which region will later become the gate region of the field effect transistor. The remaining partial regions of the cap layer 106, that is to say a first partial region 106a of the cap layer 106 and a second partial region 106b of the cap layer 106, correspondingly form a first source/drain region 106a and a second source/drain region 106b of the field effect transistor.

The wet etching of the cap layer 106 can be effected using a citric acid:H₂O₂:H₂O (25:1:75) etching solution at room temperature. Since a wet-etching etchant is used, the cap layer 106 can be etched away isotropically (along the vertical and the horizontal direction), such that lateral interspaces 109 can be manufactured between the gate 108 and the source/drain regions 106a, 106b. In this way, the gate 108 can be spatially (physically) insulated from the cap layer 106 (i.e., the first source/drain region 106a and the second source/drain region 106b), and what can be achieved is that the gate 108 is situated only on the upper surface of the GaAs channel 105 and along the sidewalls of the body of the fin structure 210. This produces a tri-gate field effect transistor (tri-gate FET) or a so-called multi-gate field effect transistor (MuGFET).

What can be achieved in another configuration of the invention is that the gate 108 is formed only on (or along) the sidewalls of the body of the fin 210, such that a double-gate device or a fin field effect transistor (FinFET) is obtained. In this case, the partial region of the upper surface of the fin structure 210, which partial region is situated between the first source/drain region 106a and the second source/drain region 106b, in other words the uncovered upper surface of the channel layer 105, can be passivated prior to the gate metallization, e.g., with a silicon nitride layer (Si₃N₄ layer).

After the gate lithography and the etching of the cap layer 106, gate metals are evaporated, for example, with the aid of an electron beam evaporation technique. Suitable gate metals for GaAs-based and InGaAs/InP-based FinFETs/MuGFETs can have a Ti/Pt/Au (20/10/350 nm) layer arrangement, that is to say a layer composed of titanium (Ti) having a thickness of approximately 20 nm, a layer composed of platinum (Pt) and arranged on the Ti layer and having a thickness of approximately 10 nm, and a layer composed of gold and arranged on the Pt layer and having a thickness of approximately 350 nm. Another combination of gate metals may be a Pt/Ti/Pt/Au (8/20/10/350 nm) layer arrangement, that is to say an 8 nm thick first Pt layer, a 20 nm thick Ti layer arranged on the first Pt layer, a 10 nm thick second Pt layer arranged on the Ti layer, and a 350 nm thick Au layer arranged on the second Pt layer.

FIG. 1H additionally shows exemplary dimensions for the field effect transistor 100. By way of example, the distance L_{sd} between the first source/drain contact 107a and the second source/drain contact 107b is shown, which distance may be approximately 2 μm to 3 μm, while the length L_{g} of the gate region 108 (gate length L_{g}) may be approximately 30 nm to 100 nm. The distance L_{gs} between a first edge 108a of the gate region 108 and the first source/drain contact 107a and/or the distance L_{gd} between a second edge 108b of the gate region 108 and the second source/drain contact 107b may be approximately 0.5 nm to 0.8 nm.

FIG. 1I and FIG. 2D show the layer arrangement 100, as a cross-sectional view and as a three-dimensional perspective view, respectively, in another process step, in which a passivation layer 110 is formed on the channel layer 105 in a region between the first source/drain region 106a and the gate 108 and in another region between the gate 108 and the second source/drain region 106b. The passivation layer 110 can be formed using a growth method such as, for example, a plasma enhanced chemical vapor deposition (PECVD) method or a cathode sputtering method (sputter method) such as, for example, a DC sputter method or an RF sputter method. The passivation layer 110 can have a silicon nitride layer (Si₃N₄ layer) having a thickness of, e.g., 50 nm to 150 nm.

A compound semiconductor field effect transistor having a fin structure (e.g., a FinFET or a MuGFET) which is manufactured in accordance with an exemplary embodiment of the invention can be normally on or normally off, depending on the threshold voltage of the device (field effect transistor), which threshold voltage optionally depends on the thickness of the fin structure 210, the fin height and the doping in the body of the fin 210.

A two-dimensional cross-sectional view of an exemplary device structure of a compound semiconductor field effect transistor 100 is illustrated in Figure 1I, in which a buffer layer 102 is formed on a substrate 101, a first layer 103 (barrier layer 103) is formed on the buffer layer 102, a second layer 104 (spacer layer 104) is formed on the first layer 103, and a third layer 105 (channel layer 105) is formed on the second layer 104. A cap layer is formed on partial regions of the third layer 105 (channel layer 105), whereby a first source/drain region 106a is formed on a first partial region of the third layer 105 and a second source/drain region 106b is formed on a second partial region of the third layer 105. A first source/drain contact 107a is formed on a partial region of the first source/drain region 106a, and a second source/drain contact 107b is formed on a partial region of the second source/drain region 106b. A gate region 108 is formed on a partial region of the upper surface of the third layer 105, between the first source/drain region 106a and the second source/drain region 106b. In addition, a passivation layer 110 is formed between the gate region 108 and the source/drain regions 106a, 106b.

Another exemplary embodiment of a compound semiconductor field effect transistor structure 300 is illustrated in FIG. 3, wherein a first layer 303, which contains a wide-band-gap Al_{0.3}Ga_{0.7}As material, is formed on the buffer layer 102. The first layer 303 once again serves as a barrier layer for suppressing charge carrier transport into the substrate 101. A second layer 304, which contains a doped GaAs material, is formed on the first layer 303 (barrier layer 303). The second layer 304 corresponds to the channel layer 105 of the field effect transistor 100 shown in FIG. 1I; in other words, the second layer 304 of the layer arrangement 300 shown in FIG. 3 serves as a channel layer 304 of the field effect transistor 300. The dopant concentration of the channel layer 304 can therefore be similar to the dopant concentration of the channel layer 105 of the field effect transistor 100.

Furthermore, the field effect transistor 300 has a third layer 305 formed on the second layer 304 (channel layer 304). The third layer 305 contains an Al_{0.3}Ga_{0.7}As material having a high energy band gap (wide-band-gap Al_{0.3}Ga_{0.7}As material).

Clearly, in the exemplary embodiment shown in FIG. 3, the doped GaAs channel layer 304 is enclosed in a sandwich-like manner between two Al_{0.3}Ga_{0.7}As wide-band-gap layers, i.e. the first layer 303 and the third layer 305.

The thickness of the Al_{0.3}Ga_{0.7}As wide-band-gap layers 303, 305 can be in each case approximately 10 nm to 20 nm, and the thickness of the channel layer 304 can likewise be approximately 10 nm to 20 nm. The thickness of the cap layer (represented by the first source/drain region 306a and the second source/drain region 306b) can be approximately 20 nm to 40 nm.

The cap layer, that is to say the first source/drain region 306a formed from the cap layer and the second source/drain region 306b formed from the cap layer, is formed as an n-doped GaAs layer having a dopant concentration of approximately 1×10¹⁸ cm⁻³ to 5×10¹⁸ cm⁻³.

The process sequence for the production of the field effect transistor 300 is the same as the one described for the field effect transistor 100 with reference to FIG. 1A to FIG. 2D.

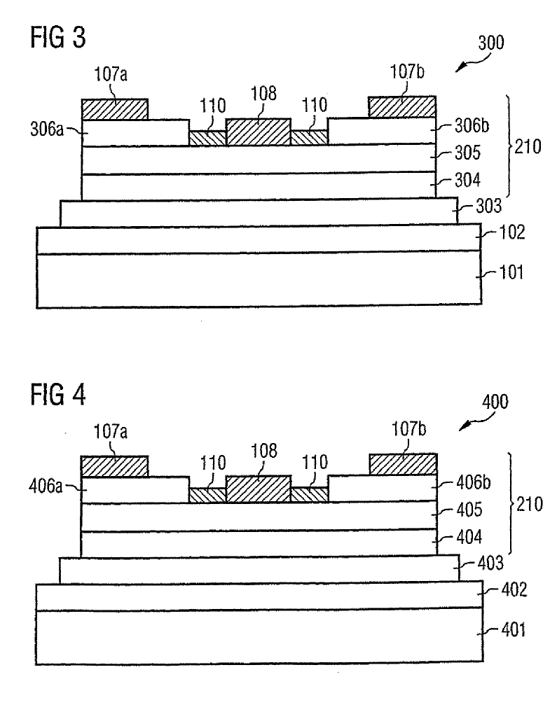

FIG. 4 shows the cross section of the layer structure of a high-mobility FinFET/MuGFET device 400 in accordance with another exemplary embodiment of the invention. The layer structure of this configuration begins with a semi-insulating substrate 401 containing indium phosphide (InP). A buffer layer 402 is formed thereon, the buffer layer containing undoped InP material. The buffer layer 402 can have a thickness of approximately 500 nm. The buffer layer 402 can furthermore improve the quality of material grown on, in comparison, e.g., with direct growth of the channel layer on the substrate 401.

After the growth of the buffer layer 402, a first layer 403 (also referred to as barrier layer 403) containing an undoped wide-band-gap Al_{0.48}In_{0.52}As material is formed (grown) on the buffer layer 402 in order to effectively suppress the charge carrier transport into the substrate 401 by creating a potential barrier. A layer thickness of approximately 100 nm to 500 nm can suffice to minimize the growth time of the barrier layer 403 and nevertheless to provide an effective barrier.

After the growth of the first layer 403, a second layer 404 is grown, which second layer 404 contains an undoped InP material. The second layer 404 can have a thickness of approximately 50 nm to 100 nm and is also referred to as a spacer layer 404.

After the growth of the second layer 404 (spacer layer 404), a third layer 405 containing a highly doped (e.g., n⁺-doped with a dopant concentration of approximately 0.5×10¹⁸ cm⁻³ to 5.0×10¹⁸ cm⁻³) In_{0.53}Ga_{0.47}As material is formed (grown) with a thickness of approximately 10 nm to 30 nm on the second layer 404. The third layer 405 serves as a channel layer 405 of the field effect transistor 400.

The compound semiconductor field effect transistor 400 having the fin structure 210 is completed by a final 10 nm to 20 nm n-doped (dopant concentration of approximately 1×10¹⁸ cm⁻³ to 5×10¹⁸ cm⁻³) In_{0.53}Ga_{0.47}As cap layer, represented in FIG. 4 by a first source/drain region 406a and a second source/drain region 406b. Since the In_{0.53}Ga_{0.47}As cap layer has a small band gap, this layer can optionally remain undoped and in this case nevertheless ensure the formation of ohmic contacts with good quality and simultaneously have a high breakdown voltage.

The complete layer sequence shown in FIG. 4 is lattice-matched to the InP substrate 401, thereby eliminating possible problems during layer growth.

In an alternative configuration of the invention, the InGaAs channel layer 405 can be replaced by a doped InP channel layer. In this way, the field effect transistor 400 can be tailored both to applications requiring a high speed (high-speed application) and to applications requiring a high power (high-power applications). The process sequence is the same as described above.

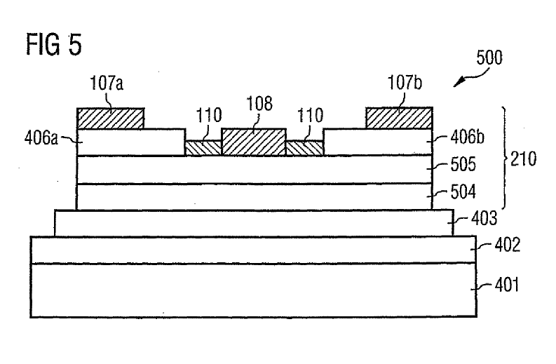

In accordance with another exemplary embodiment of the invention, an undoped wide-band-gap Al_{0.48}In_{0.52}As Schottky contact layer can be inserted directly below the gate region 108 and on the doped channel layer (n⁺-doped with a dopant concentration of approximately 0.5×10¹⁸ cm⁻³ to 5.0×10¹⁸ cm⁻³)composed of In_{0.53}Ga_{0.47}As material. The resulting field effect transistor structure 500 is shown in FIG. 5, wherein the In_{0.53}Ga_{0.47}As channel layer 504 (which in this exemplary embodiment is equivalent to the second layer 504) is formed on the first layer 403 (barrier layer 403), and wherein the Schottky contact layer 505 (which is equivalent to the third layer 505) is formed on the channel layer 504. The thickness of the third layer 505, i.e. of the wide-band-gap Al_{0.48}In_{0.52}As layer 505, and the thickness of the second layer 504, i.e. of the In_{0.53}Ga_{0.47}As channel layer 504, can be in each case approximately 10 nm to 30 nm. The entire structure 500 furthermore remains lattice-matched to the InP substrate 401.

One advantage of the arrangement shown in FIG. 5 can be seen in the fact that a reduced gate leakage current (on account of the high band gap) and better high-speed performance can be obtained since the confinement of the electrons on account of the discontinuity of the conduction band can be highly effective, as is well known in the art.

The indium proportion (indium content) in the In_{0.53}Ga_{0.47}As channel layer 504 can be varied from x=0.53 to x=0.7 in order to increase the electron mobility even further and, consequently, to obtain better high-speed performance. In this case, the maximum thickness of the channel layer 504 is restricted on account of strain produced (induced) in the channel layer 504 since the channel layer 504 is no longer lattice-matched to the InP substrate 401.

What is claimed is:

1. A method for manufacturing a compound semiconductor field effect transistor having a fin structure, the method comprising:
forming a first layer on or above a substrate, wherein the first layer comprises a first compound semiconductor material;
forming a second layer on the first layer, wherein the second layer comprises a second compound semiconductor material;
forming a third layer on the second layer, wherein the third layer comprises a third compound semiconductor material;
forming a cap layer on the third layer, wherein the cap layer comprises a fourth compound semiconductor material;
forming a fin structure by patterning the second layer, the third layer and the cap layer;
forming a first source/drain region from a first region of the cap layer and forming a second source/drain region from a second region of the cap layer; and
forming a gate region on at least one region of at least one sidewall of the fin structure and/or on a region of an upper surface of the third layer.

2. The method as claimed in claim 1, wherein the substrate comprises a semi-insulating material.

3. The method as claimed in claim 1, wherein the substrate comprises a III-V compound material.

4. The method as claimed in claim 1, further comprising:
forming a buffer layer on or over the substrate prior to forming the first layer; and
forming the first layer on the buffer layer, wherein the buffer layer comprises a fifth compound semiconductor material.

5. The method as claimed in claim 1, wherein at least one of the following layers comprises a III-V compound semiconductor material:
the first layer;
the second layer;
the third layer;
the cap layer; and/or
a buffer layer.

6. The method as claimed in claim 1, wherein the first layer comprises a semiconductor material having a large band gap.

7. The method as claimed in claim 3, wherein the substrate comprises a GaAs material or an InP material.

8. The method as claimed in claim 5, wherein the buffer layer comprises a GaAs material or an InP material.

9. The method as claimed in claim 5, wherein the first layer comprises one of the following materials:
an AlAs material;
an Al_{0.3}Ga_{0.7}As material; or
an Al_{0.48}In_{0.52}As material.

10. The method as claimed in claim 5, wherein the second layer is formed as a spacer layer, and wherein the third layer is formed as a channel layer.

11. The method as claimed in claim 5, wherein the second layer is formed as a channel layer, and wherein the third layer comprises a semiconductor material having a large band gap.

12. The method as claimed in claim 10, wherein the spacer layer comprises a GaAs material, and wherein the channel layer comprises an n-doped GaAs material.

13. The method as claimed in claim 10, wherein the spacer layer comprises an InP material, and wherein the channel layer comprises an n-doped In_{0.53}Ga_{0.47}As material.

14. The method as claimed in claim 11, wherein the channel layer comprises an n-doped GaAs material, and wherein the third layer comprises an Al_{0.3}Ga_{0.7}As material.

15. The method as claimed in claim 11, wherein the channel layer comprises an n-doped In_{0.53}Ga_{0.47}As material, and wherein the third layer comprises an Al_{0.48}In_{0.52}As material.

16. The method as claimed in claim 12, wherein the cap layer comprises an n-doped GaAs material.

17. The method as claimed in claim 13, wherein the cap layer comprises an n-doped In_{0.53}Ga_{0.47}As material.

18. The method as claimed in claim 12, wherein the channel layer has a dopant concentration of approximately 0.5×10¹⁸ cm⁻³ to 5.0×10¹⁸ cm⁻³.

19. The method as claimed in claim 16, wherein the cap layer has a dopant concentration of approximately 1×10¹⁸ cm³ to 5×10¹⁸ cm⁻³.

20. The method as claimed in claim 1, wherein the fin structure has a width of about 25 nm to about 50 nm.

21. The method as claimed in claim 1, wherein forming a gate region comprises using an electron beam lithography method.

22. The method as claimed in claim 1, wherein forming a gate region comprises forming a gate recess.

23. The method as claimed in claim 22, wherein forming the gate recess comprises using a wet etching method or a dry etching method.

24. The method as claimed in claim 1, wherein forming a gate region comprises:
forming an insulating layer on the at least one region of the at least one sidewall of the fin structure and/or on the region of the upper surface of the third layer; and
forming an electrically conductive layer on the insulating layer.

25. The method as claimed in claim 24, wherein forming the electrically conductive layer comprises using an electron beam evaporation method.

26. A compound semiconductor field effect transistor comprising a fin structure, the field effect transistor comprising:
a first layer disposed on or above a substrate, wherein the first layer comprises a first compound semiconductor material;
a second layer disposed on the first layer, wherein the second layer comprises a second compound semiconductor material;
a third layer disposed on the second layer, wherein the third layer comprises a third compound semiconductor material;
a cap layer disposed on at least one region of the third layer, wherein the cap layer comprises a fourth compound semiconductor material, and wherein the second layer, the third layer and the cap layer are patterned in such a way that a fin structure is formed;
a first source/drain region, within a first region of the cap layer and a second source/drain region, within a second region of the cap layer; and
a gate region disposed over at least one region of at least one sidewall of the fin structure and/or over a region of an upper surface of the third layer.

27. The field effect transistor as claimed in claim 26, wherein the substrate comprises a semi-insulating material.

28. The field effect transistor as claimed in claim 26, wherein the substrate comprises a III-V compound material.

29. The field effect transistor as claimed in claim 26, further comprising a buffer layer disposed between the substrate and the first layer, wherein the buffer layer comprises a fifth compound semiconductor material.

30. The field effect transistor as claimed in claim 26, wherein at least one of the following layers comprises a III-V compound semiconductor material:
the first layer;
the second layer;
the third layer;
the cap layer; and/or
a buffer layer.

31. The field effect transistor as claimed in claim 26, wherein the first layer comprises a semiconductor material having a large band gap.

32. The field effect transistor as claimed in claim 26, wherein the second layer is formed as a spacer layer, and wherein the third layer is formed as a channel layer.

33. The field effect transistor as claimed in claim 26, wherein the second layer is formed as a channel layer, and wherein the third layer comprises a semiconductor material having a large band gap.
